(19) United States
(12) Patent Application Publication
(10) Pub. No.: US 2023/0008674 A1
(43) Pub. Date: Jan. 12, 2023

(54) LIQUID CRYSTAL POLARIZERS FOR IMAGING

(71) Applicant: Meta Platforms Technologies, LLC, Menlo Park, CA (US)

(72) Inventors: Qing Chao, Redmond, WA (US); Hao Yu, Kent, OH (US); Lu Lu, Kirkland, WA (US); Scott Charles McEldowney, Redmond, WA (US); Xinqiao Liu, Medina, WA (US); Eric Fest, Seattle, WA (US)

(21) Appl. No.: 17/850,898

(22) Filed: Jun. 27, 2022

Related U.S. Application Data
(60) Provisional application No. 63/218,605, filed on Jul. 6, 2021.

(51) Int. Cl. G02B 5/30; G02B 3/00; H04N 5/369; H04N 5/33

(52) U.S. Cl. CPC G02B 5/3016; G02B 3/005; H04N 5/3696; H04N 5/33

(57) ABSTRACT

An image sensor includes imaging pixels and a patterned liquid crystal polarizer (LCP). The imaging pixel include subpixels. The patterned LCP is disposed over the subpixels and configured to direct a particular polarized portion of imaging light to particular subpixels.

### CROSS-REFERENCE TO RELATED APPLICATIONS

This application claims priority to U.S. provisional Application No. 63/218,605 filed Jul. 6, 2021, which is hereby incorporated by reference.

### TECHNICAL FIELD

This disclosure relates generally to optics, and in particular to polarizers.

### BACKGROUND INFORMATION

Optical components in devices include refractive lenses, diffractive lenses, color filters, neutral density filters, and polarizers. Linear and circular polarizers are common-place in both commercial and consumer systems and devices, for example. Wire-grid polarizers are a common polarizer.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified.

FIGS. 1A-1F illustrate various subpixels having Liquid Crystal Polarizers (LCPs) for sensing different polarization orientations of incident imaging light, in accordance with aspects of the disclosure.

FIGS. 2A-2B illustrate a Liquid Crystal Pancharatnam-Berry Phase (LC-PBP) lens disposed over a pair of subpixels configured to sense circularly polarized light, in accordance with aspects of the disclosure.

FIG. 3 illustrates an LCP arranged with regions to be disposed over subpixels to achieve Full Stokes Imaging, in accordance with aspects of the disclosure.

FIG. 4 illustrates an LCP arranged with regions to be disposed over subpixels to provide polarization difference imaging (PDI), in accordance with aspects of the disclosure.

FIG. 5 illustrates an LCP arranged with regions to be disposed over subpixels to provide PDI for 45-degree polarization and 135-degree polarization differences, in accordance with aspects of the disclosure.

FIG. 6 illustrates an LCP arranged with regions to be disposed over subpixels to provide PDI for right-hand circular (RHC) polarization and left-hand circular (LHC) polarization differences, in accordance with aspects of the disclosure.

FIG. 7 illustrates an imaging system including an image pixel array, in accordance with aspects of the disclosure.

FIGS. 8A-8D illustrate an example imaging system for imaging circularly polarized light, in accordance with aspects of the disclosure.

FIG. 9 illustrates an imaging system that utilizes a patterned PBP lens to function as a microlens and to direct LHC polarized light and RHC polarized light to different subpixels, in accordance with aspects of the disclosure.

### DETAILED DESCRIPTION

Embodiments of liquid crystal polarizers are described herein. In the following description, numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Throughout this specification, several terms of art are used. These terms are to take on their ordinary meaning in the art from which they come, unless specifically defined herein or the context of their use would clearly suggest otherwise.

In some implementations of the disclosure, the term “near-eye” may be defined as including an element that is configured to be placed within 50 mm of an eye of a user while a near-eye device is being utilized. Therefore, a “near-eye optical element” or a “near-eye system” would include one or more elements configured to be placed within 50 mm of the eye of the user.

In aspects of this disclosure, visible light may be defined as having a wavelength range of approximately 380 nm-700 nm. Non-visible light may be defined as light having wavelengths that are outside the visible light range, such as ultraviolet light and infrared light. Infrared light having a wavelength range of approximately 700 nm-1 mm includes near-infrared light. In aspects of this disclosure, near-infrared light may be defined as having a wavelength range of approximately 700 nm-1.4 μm.

In aspects of this disclosure, the term “transparent” may be defined as having greater than 90% transmission of light. In some aspects, the term “transparent” may be defined as a material having greater than 90% transmission of visible light.

Wire-grid polarizers are traditionally used in products for infrared applications. However, micropatterned wire-grid polarizers have (1) limited spatial resolution, (2) poor performance at visible wavelengths, (3) require complicated lithographic processing, and (4) are susceptible to defects.

In this disclosure, a liquid crystal polarizer (LCP) fabricated by photoalignment of absorbing materials is disclosed as an alternative to creating patterned polarizers (e.g. micro-patterned wire-grid polarizers) for particular imaging systems. The LCP may be fabricated with polymers and photoalignment of absorbing materials. The photoalignment of absorbing materials in polymers can produce micron-sized polarizers of high efficiency and extinction for ultraviolet (UV), visible, and near-infrared (NIR) wavelengths. In some implementations, the absorbing materials are dimensions at less than 10 microns. In some implementations, the features may be as small as 2.5 microns. In some implementations, the LCP includes twisted liquid crystals. In some implementations, the LCP includes untwisted liquid crystals. In some implementations, the LCP includes both twisted liquid crystals and untwisted liquid crystals.

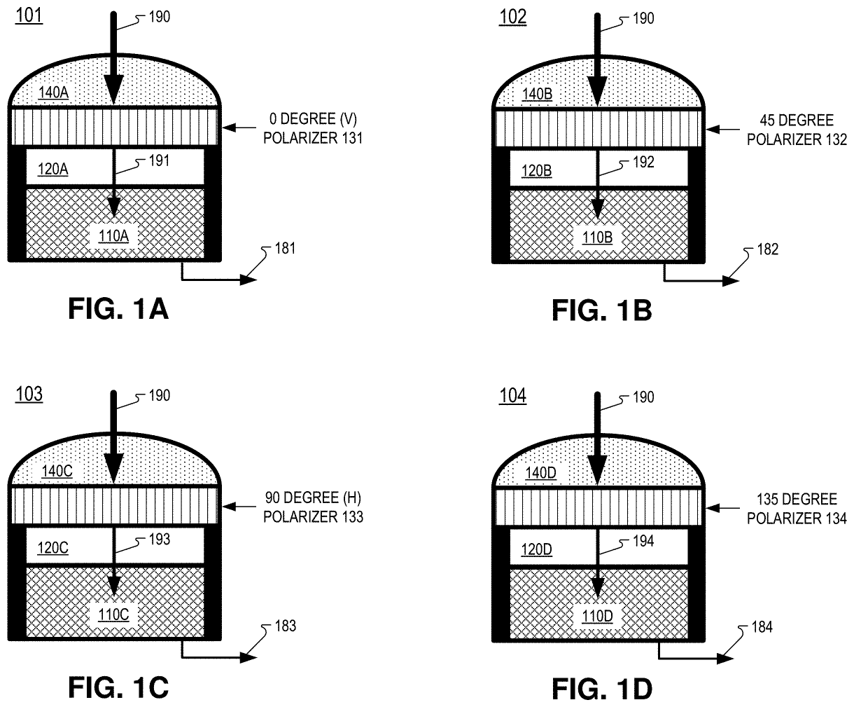

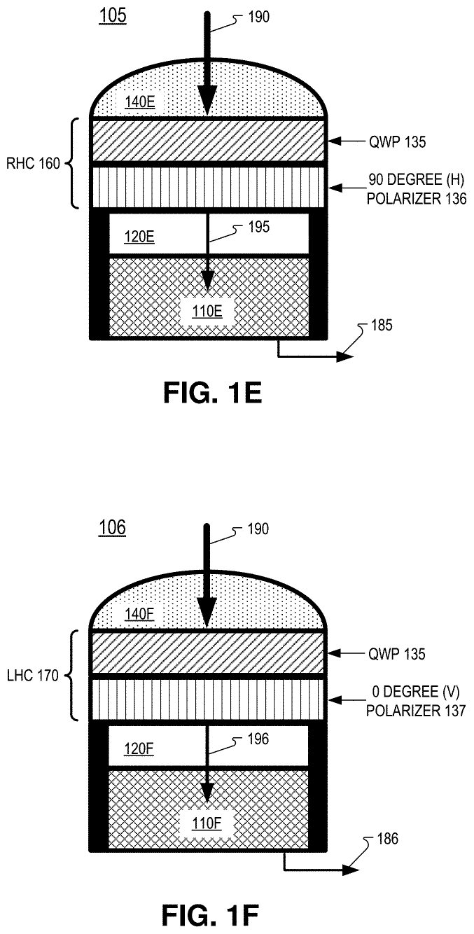

In implementations of the disclosure, a CMOS sensor with Liquid Crystal polarizers (LCP) is disclosed that allows for full or partial Stokes imaging (e.g. FIG. 1). In some implementations, a liquid crystal (LC) Pancharatnam-Berry phase (PBP) lens is included with an optical sensor.

An implementation of the disclosure includes an optical sensor with a patterned liquid crystal polarizer on top of a photo-sensitive region with photodiode(s) beneath it to measure Stokes parameters for polarization imaging. Above the patterned LCP, there can be a light guiding element (for e.g. microlens) to improved optical efficiency. Between the patterned LCP and the photon-sensitive region, there can be optional optical structures including filter, high absorption protrusion, back side metals, deep trench interface and polarization sensitive element. Deep Trench Interface (DTI) can be added around the boundaries of the photosensitive region (e.g. silicon) for each pixel, to reduce crosstalk between pixels.

Another implementation of the disclosure includes an optical sensor with a patterned liquid crystal polarizer on top of a photo-sensitive region with photodiode(s) beneath it to measure partial Stokes parameters for polarization difference imaging. Above the patterned LCP, there can be a light guiding element (for e.g. microlens) to improved optical efficiency. Between the patterned LCP and the photo-sensitive region, there can be optional optical structures including filter, high absorption protrusion, back side metals, deep trench interface and polarization sensitive element.

Some implementations of the disclosure may include a LC-PBP lens disposed over photodiodes(s) to measure components of RHC and LHC for polarization imaging. These and other embodiments are described in more detail in connection with FIGS. 1-9.

FIGS. 1A-1F illustrate various subpixels having Liquid Crystal Polarizers (LCP) for sensing different polarization orientations of incident imaging light, in accordance with aspects of the disclosure. FIGS. 1A-1D are subpixels configured to sense various orientations of linearly polarized light and FIGS. 1E-1F are subpixels configured to sense circularly polarized light.

FIG. 1A illustrates subpixel 101 configured to sense a vertically polarized portion of image light 190. Vertically polarized light may also be referred to as 0-degree linearly polarized light, in the disclosure. Subpixel 101 includes a microlens 140A, a semiconductor substrate region 110A, a high absorption layer 120A, and a 0-degree (vertical) polarizer 131 that is implemented as an LCP. Semiconductor substrate region 110A may be made of silicon, for example. A Deep Trench Interface (DTI) may be optionally included around a boundary of the high absorption layer 120A and the semiconductor substrate region 110A to separate adjacent subpixels. In FIG. 1A, high absorption layer 120A is disposed between semiconductor substrate region 110A and 0-degree (vertical) polarizer 131. 0-degree (vertical) polarizer 131 is disposed between microlens 140A and high absorption layer 120A.

In operation, imaging light 190 is incident on subpixel 101 and microlens 140A focuses the imaging light 190 to semiconductor substrate region 110A. 0-degree (vertical) polarizer 131 passes the vertically polarized portion 191 of imaging light 190 and blocks/rejects other polarizations of imaging light 190. Vertically polarized portion 191 of imaging light 190 becomes incident on semiconductor substrate region 110A and generates a first imaging signal 181 in response to the intensity of the vertically polarized portion 191 of imaging light 190.

FIG. 1B illustrates subpixel 102 configured to sense a 45-degree polarized portion of image light 190. 45-degree polarized light may also be referred to as 45-degree linearly polarized light, in the disclosure. Subpixel 102 includes a microlens 140B, a semiconductor substrate region 110B, a high absorption layer 120B, and a 45-degree polarizer 132 that is implemented as an LCP. Semiconductor substrate region 110B may be made of silicon, for example. A Deep Trench Interface (DTI) may be optionally included around a boundary of the high absorption layer 120B and the semiconductor substrate region 110B to separate adjacent subpixels. In FIG. 1B, high absorption layer 120B is disposed between semiconductor substrate region 110B and 45-degree polarizer 132. 45-degree polarizer 132 is disposed between microlens 140B and high absorption layer 120B.

In operation, imaging light 190 is incident on subpixel 102 and microlens 140B focuses the imaging light 190 to semiconductor substrate region 110B. 45-degree polarizer 132 passes the 45-degree polarized portion 192 of imaging light 190 and blocks/rejects other polarizations of imaging light 190. 45-degree polarized portion 192 of imaging light 190 becomes incident on semiconductor substrate region 110B and generates a second imaging signal 182 in response to the intensity of the 45-degree polarized portion 192 of imaging light 190.

FIG. 1C illustrates subpixel 103 configured to sense a horizontally polarized portion of image light 190. Horizontally polarized light may also be referred to as 90-degree linearly polarized light, in the disclosure. Subpixel 103 includes a microlens 140C, a semiconductor substrate region 110C, a high absorption layer 120C, and a 90-degree (horizontal) polarizer 133 that is implemented as an LCP. Semiconductor substrate region 110C may be made of silicon, for example. A Deep Trench Interface (DTI) may be optionally included around a boundary of the high absorption layer 120C and the semiconductor substrate region 110C to separate adjacent subpixels. In FIG. 1C, high absorption layer 120C is disposed between semiconductor substrate region 110C and 90-degree (horizontal) polarizer 133. 90-degree (horizontal) polarizer 133 is disposed between microlens 140C and high absorption layer 120C.

In operation, imaging light 190 is incident on subpixel 103 and microlens 140C focuses the imaging light 190 to semiconductor substrate region 110C. 90-degree (horizontal) polarizer 133 passes the horizontally polarized portion 193 of imaging light 190 and blocks/rejects other polarizations of imaging light 190. Horizontally polarized portion 193 of imaging light 190 becomes incident on semiconductor substrate region 110C and generates a third imaging signal 183 in response to the intensity of the horizontally polarized portion 193 of imaging light 190.

FIG. 1D illustrates subpixel 104 configured to sense a 135-degree polarized portion of image light 190. 135-degree polarized light may also be referred to as 135-degree linearly polarized light, in the disclosure. Subpixel 104 includes a microlens 140D, a semiconductor substrate region 110D, a high absorption layer 120D, and a 135-degree polarizer 134 that is implemented as an LCP. Semiconductor substrate region 110D may be made of silicon, for example. A Deep Trench Interface (DTI) may be optionally included around a boundary of the high absorption layer 120D and the semiconductor substrate region 110D to separate adjacent subpixels. In FIG. 1D, high absorption layer 120D is disposed between semiconductor substrate region 110D and 135-degree polarizer 134. 135-degree polarizer 134 is disposed between microlens 140D and high absorption layer 120D.

In operation, imaging light 190 is incident on subpixel 104 and microlens 140D focuses the imaging light 190 to semiconductor substrate region 110D. 135-degree polarizer 134 passes the 135-degree polarized portion 194 of imaging light 190 and blocks/rejects other polarizations of imaging light 190. 135-degree polarized portion 194 of imaging light 190 becomes incident on semiconductor substrate region 110D and generates a fourth imaging signal 184 in response to the intensity of the 135-degree polarized portion 194 of imaging light 190.

FIG. 1E illustrates an example subpixel 105 configured to sense a right-hand circularly (RHC) polarized portion of image light 190. Subpixel 105 includes a microlens 140E, a semiconductor substrate region 110E, a high absorption layer 120E, and an RHC polarizing layer 160. RHC polarizing layer 160 includes a quarter-waveplate (QWP) 135 and a 90-degree (horizontal) polarizer 136 that is implemented as an LCP. Fast axis alignment between QWP 135 and polarizer 136 may be required for example subpixel 105. Semiconductor substrate region 110E may be made of silicon, for example. A Deep Trench Interface (DTI) may be optionally included around a boundary of the high absorption layer 120E and the semiconductor substrate region 110E to separate adjacent subpixels. In FIG. 1E, high absorption layer 120E is disposed between semiconductor substrate region 110E and RHC polarizing layer 160. RHC polarizing layer 160 is disposed between microlens 140E and high absorption layer 120E.

In operation, imaging light 190 is incident on subpixel 105 and microlens 140E focuses the imaging light 190 to semiconductor substrate region 110E. RHC polarizing layer 160 passes the RHC polarized portion 195 of imaging light 190 and blocks/rejects other polarizations of imaging light 190. RHC polarized portion 195 of imaging light 190 becomes incident on semiconductor substrate region 110E and generates a fifth imaging signal 185 in response to the intensity of the RHC polarized portion 195 of imaging light 190.

FIG. 1F illustrates an example subpixel 106 configured to sense a left-hand circularly (LHC) polarized portion of image light 190. Subpixel 106 includes a microlens 140F, a semiconductor substrate region 110F, a high absorption layer 120F, and a LHC polarizing layer 170. LHC polarizing layer 170 includes a QWP 135 and a 0-degree (vertical) polarizer 137 that is implemented as an LCP. Fast axis alignment between QWP 135 and polarizer 137 may be required for example subpixel 106. Semiconductor substrate region 110F may be made of silicon, for example. A Deep Trench Interface (DTI) may be optionally included around a boundary of the high absorption layer 120F and the semiconductor substrate region 110F to separate adjacent subpixels. In FIG. 1F, high absorption layer 120F is disposed between semiconductor substrate region 110F and LHC polarizing layer 170. LHC polarizing layer 170 is disposed between microlens 140F and high absorption layer 120F.

In operation, imaging light 190 is incident on subpixel 106 and microlens 140F focuses the imaging light 190 to semiconductor substrate region 110F. LHC polarizing layer 170 passes the LHC polarized portion 196 of imaging light 190 and blocks/rejects other polarizations of imaging light 190. LHC polarized portion 196 of imaging light 190 becomes incident on semiconductor substrate region 110F and generates a sixth imaging signal 186 in response to the intensity of the LHC polarized portion 196 of imaging light 190.

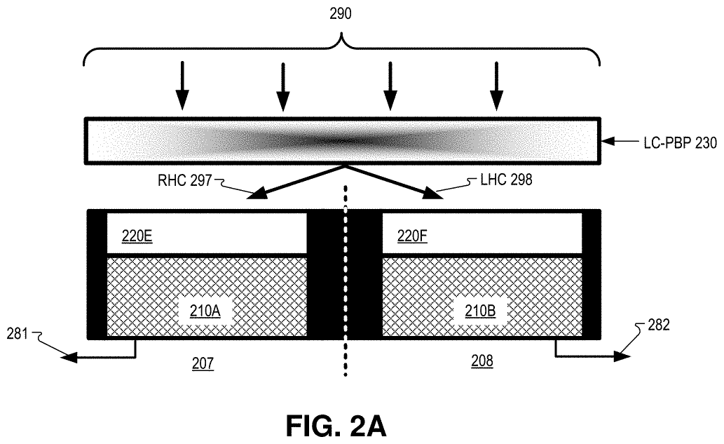

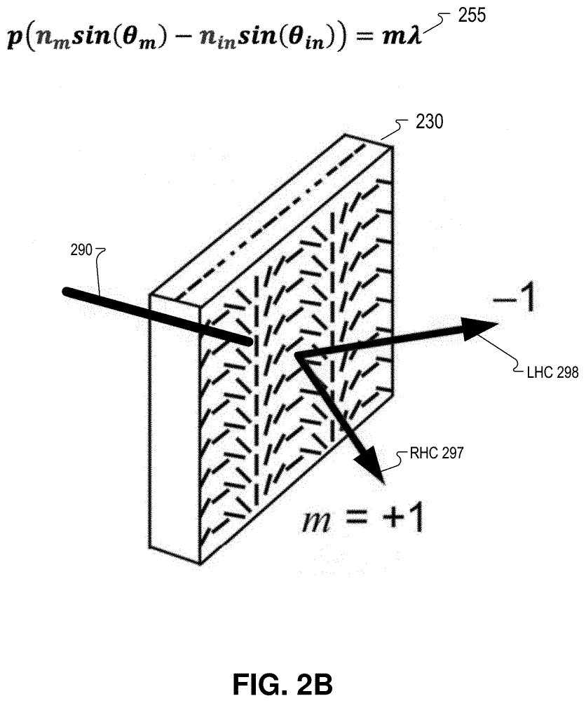

FIGS. 2A and 2B illustrate an LC-PBP lens disposed over a pair of subpixels configured to sense circularly polarized light, in accordance with aspects of the disclosure. FIG. 2A includes a LC-PBP lens 230 disposed over subpixel 207 and subpixel 208. Subpixel 207 includes an optional high absorption layer 220E and a semiconductor substrate region 210A. Subpixel 208 includes an optional high absorption layer 220F and a semiconductor substrate region 210F. Subpixel 207 is configured to sense the RHC polarized portion 297 of image light 290 and subpixel 208 is configured to sense the LHC polarized portion 298 of image light 290. LC-PBP lens 230 is configured to direct the RHC polarized portion 297 of imaging light 290 to subpixel 207. RHC polarized portion 297 of imaging light 290 becomes incident on semiconductor substrate region 210A and generates imaging signal 281 in response to the intensity of the RHC polarized portion 297 of imaging light 290. LC-PBP lens 230 is configured to direct the LHC 298 portion of imaging light 290 to subpixel 208. LHC polarized portion 298 of imaging light 290 becomes incident on semiconductor substrate region 210B and generates imaging signal 282 in response to the intensity of the LHC polarized portion 298 of imaging light 290.

FIG. 2B illustrates a perspective view of an example LC-PBP lens 230, in accordance with aspects of the disclosure. In FIG. 2B, LC-PBP lens 230 is configured to diffract the RHC polarized portion 297 of imaging light 290 at a +1 diffraction order and configured to diffract the LHC polarized portion 298 of imaging light 290 at a −1 diffraction order. Equation 255 of FIG. 2B provides an equation for designing the period (p) of LC-PBP lens 230 with respect to the desired order of diffraction (m), wavelength (λ), angle of incidence θᵢₙ of imaging light 290, and angle of diffraction θₙ, for a given diffraction order. nᵢₙ in equation 255 represent the refractive index of a material (e.g. a 1.5 refractive index of a microlens) that light 290 encounters prior to LC-PBP lens 230 and nₘ in equation 255 represents the refractive index encountered by LHC polarized portion 298 of imaging light 290 and LHC polarized portion 298 of imaging light 290.

Hence, subpixels 105 and 106 of FIGS. 1E and 1F or subpixels 207 and 208 may be used to sense circularly polarized portions of imaging light. In some implementations, LC-PBP lens 230 is designed to include the functionality of microlens 140E or 140F so that a refractive microlens can be eliminated for subpixels 207 and 208. This may advantageously save fabrication steps, fabrication materials, and decrease the size of a given imaging system.

FIGS. 1A-2B illustrate using an LCP layer for various subpixels for imaging (1) vertical linearly polarized light; (2) 45-degree linearly polarized light; (3) horizontally linearly polarized light; (4) 135-degree linearly polarized light; (5) RHC polarized light; and (6) LHC polarized light. Thus, the example subpixels may be combined into pixels capable of Stokes Imaging, partial-Stokes Imaging, and polarization difference imaging (PDI). The Stokes parameters are as follows:

S₀=Horizontal+Vertical

S₁=Horizontal−Vertical

S₂=45°-(135°)

S₃=LHC−RHC

Those skilled in the art appreciate that the reference coordinate system for “vertical,” 45-degree, “horizontal,” and 135-degree can be rotated arbitrarily in different implementations as long as the angles of transmission differ by 45 degrees from each other. In addition, there may be a margin range for each polarization orientation. For example, the term “45-degree linearly polarized light” may include 40 degree to 50 degree linearly polarized light and the term “135-degree linearly polarized light” may include 130 degree to 140 degree linearly polarized light.

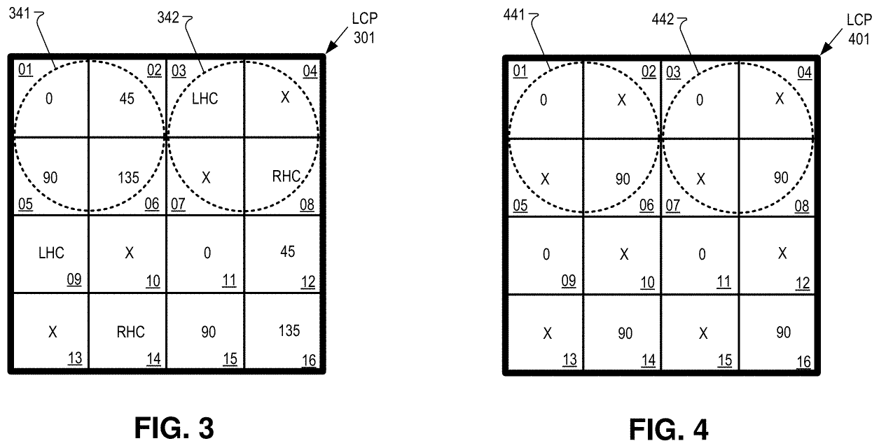

FIG. 3 illustrates an LCP 301 arranged with regions to be disposed over subpixels to achieve Full Stokes Imaging, in accordance with aspects of the disclosure. LCP 301 includes regions 01, 02, 03, 04, 05, 06, 07, 08, 09, 10, 11, 12, 13, 14, 15, and 16. Region 01 of LCP 301 is configured to pass vertically polarized light (0) to a photodiode disposed below region 01; region 02 of LCP 301 is configured to pass 45-degree polarized light (45) to a photodiode disposed below region 02; region 05 of LCP 301 is configured to pass horizontally polarized light (90) to a photodiode disposed below region 05; and region 06 of LCP 301 is configured to pass 135-degree polarized light (135) to a photodiode disposed below region 06. A refractive microlens 341 may be optionally disposed over regions 01, 02, 05, and 06 to focus imaging light to the subpixels.

Region 03 of LCP 301 is configured to pass LHC polarized light to a photodiode disposed below region 03 and region 08 of LCP 301 is configured to pass RHC polarized light to a photodiode disposed below region 08. Subpixels disposed below regions 04 (X) and 07 (X) of LCP 301 may be configured to sense infrared light, visible light, and/or specific bandwidths of visible light and infrared light. In an implementation, at least one of region 04 or region 07 is configured to sense horizontally polarized light and vertically polarized light to generate an intensity signal. A refractive microlens 342 may optionally be disposed over regions 03, 04, 07, and 08 to focus imaging light to the subpixels.

FIG. 3 shows that some of the patterns of LCP 301 may be continued or repeated so that a plurality of pixels includes the subpixels described above. In some implementations, the polarizers of subpixels 101, 102, 103, 104, 105, 106, 207, and 208 may be implemented as regions of LCP 301 where LCP 301 may be a contiguous material. A contiguous LCP 301 may cover an entire image sensor where the image sensor includes thousands or millions of imaging pixels.

FIG. 4 illustrates an LCP 401 arranged with regions to be disposed over subpixels to provide polarization difference imaging (PDI), in accordance with aspects of the disclosure. Polarization differences in the portions of the retina of some animals (e.g. fish) have been shown to be advantageous for survival and imaging polarization differences in incident light can also assist in determining the surface of objects in the environment. LCP 401 is configured to provide linear polarization difference imaging, and in particular, horizontal polarization and vertical polarization differences. Notably, the arrangement of LCP 401 may be used to calculate the first Stokes parameter: S₁=Horizontal−Vertical.

LCP 401 includes regions 01, 02, 03, 04, 05, 06, 07, 08, 09, 10, 11, 12, 13, 14, 15, and 16. The configuration of each region is notated similarly to the notation of the regions of LCP 301 (e.g. 0, 90, X). A refractive microlens 441 may be optionally disposed over regions 01, 02, 05, and 06 of LCP 401 to focus imaging light to the subpixels. A refractive microlens 442 may optionally be disposed over regions 03, 04, 07, and 08 of LCP 401 to focus imaging light to the subpixels.

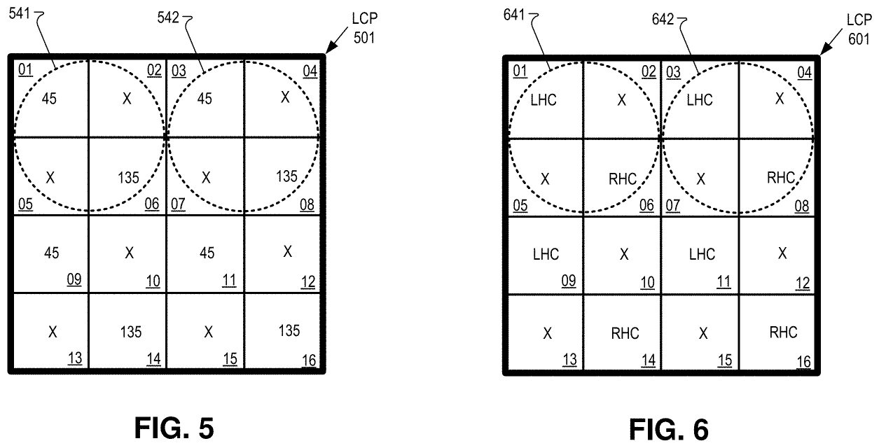

FIG. 5 illustrates an LCP 501 arranged with regions to be disposed over subpixels to provide PDI for 45-degree polarization and 135-degree polarization differences, in accordance with aspects of the disclosure. Notably, the arrangement of LCP 501 may be used to calculate the second Stokes parameter: S₂=45°-(135°). LCP 501 includes regions 01, 02, 03, 04, 05, 06, 07, 08, 09, 10, 11, 12, 13, 14, 15, and 16. The configuration of each region is notated similarly to the notation of the regions of LCP 301 (e.g. 45, 135, X). A refractive microlens 541 may be optionally disposed over regions 01, 02, 05, and 06 of LCP 501 to focus imaging light to the subpixels. A refractive microlens 542 may optionally be disposed over regions 03, 04, 07, and 08 of LCP 501 to focus imaging light to the subpixels.

FIG. 6 illustrates an LCP 601 arranged with regions to be disposed over subpixels to provide PDI for RHC polarization and LHC polarization differences, in accordance with aspects of the disclosure. Notably, the arrangement of LCP 601 may be used to calculate the third Stokes parameter: S₃=LHC−RHC. LCP 601 includes regions 01, 02, 03, 04, 05, 06, 07, 08, 09, 10, 11, 12, 13, 14, 15, and 16. The configuration of each region is notated similarly to the notation of the regions of LCP 301 (e.g. LHC, RHC, X). A refractive microlens 641 may be optionally disposed over regions 01, 02, 05, and 06 of LCP 601 to focus imaging light to the subpixels. A refractive microlens 642 may optionally be disposed over regions 03, 04, 07, and 08 of LCP 601 to focus imaging light to the subpixels. While FIGS. 3-6 illustrate example polarization arrangements, other arrangements are of course possible, in accordance with aspects of the disclosure.

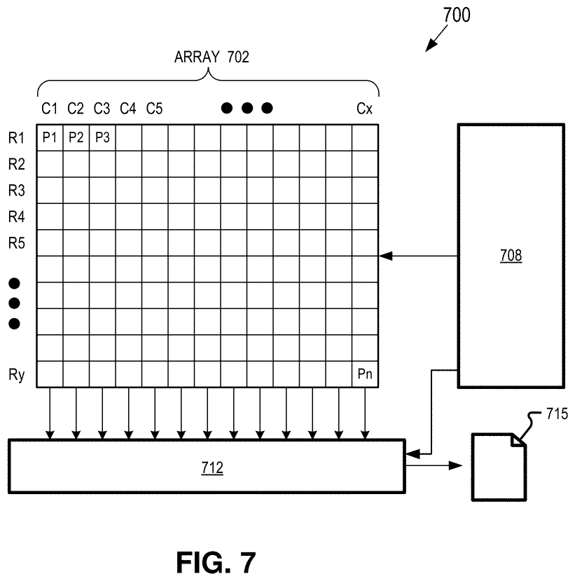

FIG. 7 illustrates an imaging system 700 including an image pixel array 702, in accordance with aspects of the disclosure. All or portions of imaging system 700 may be included in an image sensor, in some implementations. Imaging system 700 includes control logic 708, processing logic 712, and image pixel array 702. Image pixel array 702 may be arranged in rows and columns where integery is the number of rows and integer x is the number of columns. The image pixel array 702 may have a total of n pixel (P) and integer n may be the product of integer x and integery. In some implementations, n is over one million imaging pixels. Each imaging pixel may include a portion of the subpixels described in the disclosure (e.g. 101, 102, 103, 104, 105, 106, 207, and/or 208).

In operation, control logic 708 drives image pixel array 702 to capture an image. Image pixel array 702 may be configured to have a global shutter or a rolling shutter, for example. Each subpixel may be configured in a 3-transistor (3T) or 4-transistor (4T) readout circuit configuration. Processing logic 712 is configured to receive the imaging signals from each subpixel. Processing logic 712 may perform further operations such as subtracting or adding some imaging signals from other imaging signals. For example, determining a Stokes parameter may require adding imaging signals or subtracting imaging signal from various subpixels. Processing logic 712 may be configured to generate a partial-Stokes image 715 in response to first signals 181, second signals 182, third signals 183, and fourth signals 184 from all the subpixels in image pixel array 702. In an implementation where LCP 301 was disposed over image pixel array 702, processing logic 712 may be configured to generate a full-Stokes image 715 in response to first signals 181, second signals 182, third signals 183, fourth signals 184, fifth signals 185/281, and sixth signals 186/282 from all the subpixels in image pixel array 702. Processing logic 712 may also be configured to assist in generating a PDI image 715 where LCP 401, 501, or 601 are disposed over image pixel array 702.

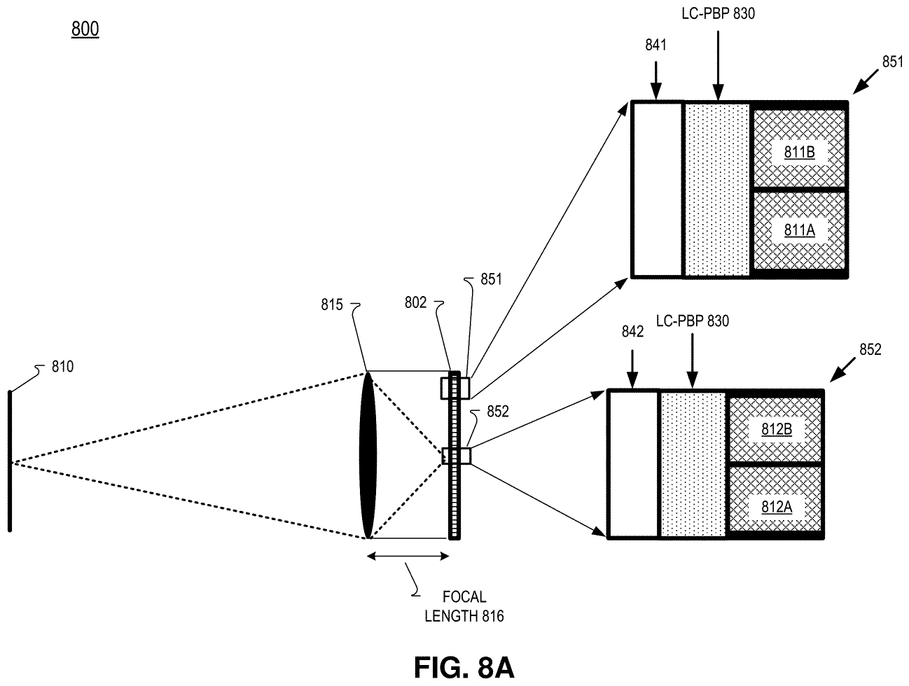

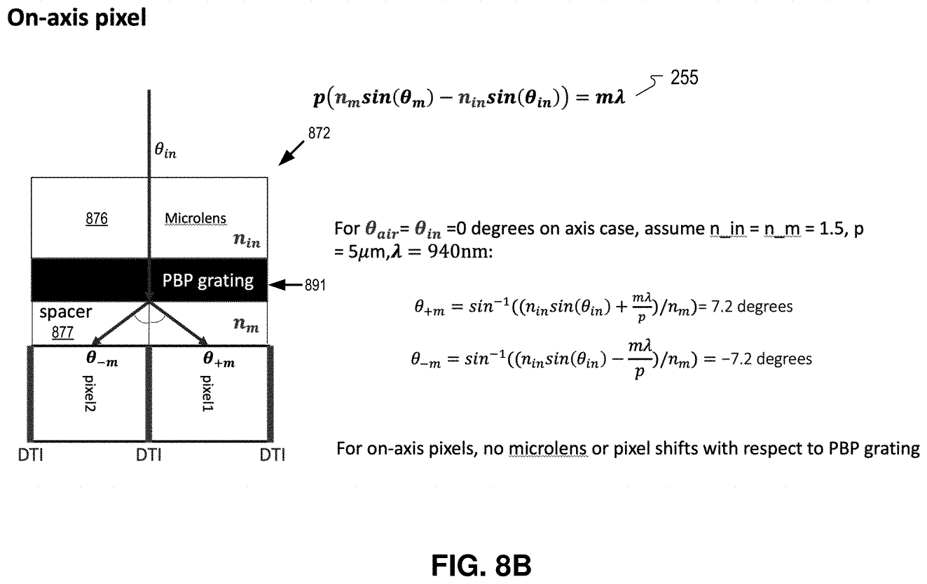

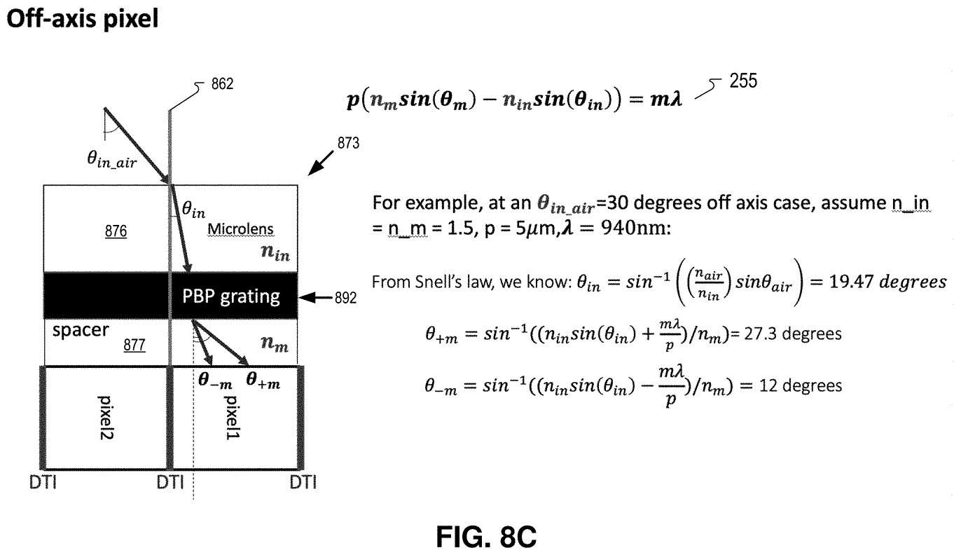

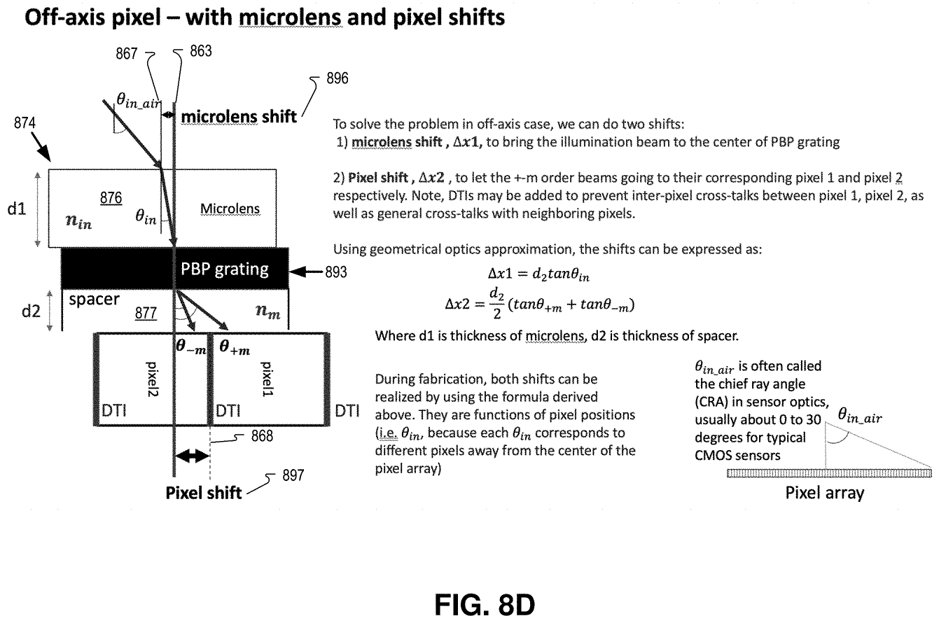

FIG. 8A illustrates an example imaging system 800 for imaging circularly polarized light, in accordance with implementations of the disclosure. Imaging system 800 includes an object 810, a focusing element 815 having a focal length 816, and an image pixel array 802. Focusing element 815 focuses image light scattered/reflected from object 810 to image pixel array 802.

Image pixel array 802 includes an on-axis pixel 852. On-axis pixel 852 may be disposed in a center of image pixel array 802 and may receive the image light from a middle of focusing element 815. Image pixel 852 includes a first subpixel 812A and a second subpixel 812B. First subpixel 812A is configured to receive RHC polarized light and second subpixel 812B is configured to receive LHC polarized light. Microlens 842 may be configured to focus light to first subpixel 812A and a second subpixel 812B.

Image pixel array 802 also includes off-axis pixel 851 disposed closer to an outside boundary of the image pixel array 802 than on-axis pixel 851. Image pixel 851 includes a first subpixel 811A and a second subpixel 811B. First subpixel 811A is configured to receive RHC polarized light and second subpixel 811B is configured to receive LHC polarized light. Microlens 841 may be configured to focus light to first subpixel 811A and a second subpixel 811B.

A contiguous LC-PBP 830 may be disposed over subpixels 811A, 811B, 812A, 812B (and all the image pixels in image pixel array 802). LC-PBP 830 may be configured similarly to LC-PBP 230 of FIGS. 2A and 2B to direct the RHC light to subpixels 811A and 812A while directing the LHC light to subpixels 811B and 812B. In an implementation. In an implementation, first subpixel 811A and second subpixel 811B of off-axis pixel 851 has a larger semiconductor substrate size than the first subpixel 812A and the second subpixel 812B of on-axis pixel 852.

FIG. 8B illustrates an example on-axis imaging pixel 872, in accordance with aspects of the disclosure. On-axis imaging pixel 872 may be an example of pixel 852, for example. On-axis imaging pixel 872 has no microlens shift nor pixel position shift (e.g. pixel1 and pixel2) with respect to PBP 891. Microlens 876 has a refractive index of nm and spacer layer 877 has a refractive index of nₘ. The refractive index for nₘ may be 1.5, the refractive index for nₘ may be 1.5. The angle of incidence θᵢₙ of imaging light is zero in FIG. 8B.

FIG. 8C illustrates an off-axis imaging pixel 873 where PBP grating 892 is unable to diffract image light to pixel 2. The angle of incidence in air θ_{in_air} of imaging light is 30 degrees off axis and the angle of incidence θᵢₙ on PBP grating 892 is 19.47 degrees in the example of FIG. 8C. Line 862 in FIG. 8C represents the center of the PBP grating. FIG. 8C illustrates that θ₋ₘ is 12 degrees and θ₊ₘ is 27.3 degrees and consequently, pixel2 does not receive image light.

FIG. 8D illustrates an example off-axis imaging pixel 874 that may improve the off-axis design of off-axis pixel 873, in accordance with aspects of the disclosure. Off-axis pixel 874 may be an example of pixel 852, for example. Off-axis pixel 874 has a microlens shift 896 with respect to a center 863 of PBP 893. Microlens shift 896 is the dimensions between center 863 of PBP 893 and the optical axis 867 of microlens 876. FIG. 8D also illustrates a pixel position shift 897 with respect to center 863 of PBP 893. Pixel position shift 897 is the dimension between center 863 of PBP 893 and a dividing line 868 between pixel1 and pixel2. Microlens 876 has a refractive index of nₘ and spacer layer 877 has a refractive index of nₘ. The refractive index for nᵢₙ may be 1.5, the refractive index for nₘ may be 1.5. The thickness of microlens 876 is d1 and the thickness of spacer 877 is d2.

Hence, FIG. 8D illustrates the microlens shift 896 for a particular imaging pixel brings the image light to the center 863 of PBP 893. And, pixel shift 897 is dimensioned so that the angle of θ₋ₘ and θ₊ₘ still allows pixel2 to receive a first diffraction order and pixel1 to receive the second diffraction order of light diffracted by PBP 893. In an implementation, dividing line 868 between the pixel1 and pixel2 is offset from PBP 893 in a first direction and the optical axis 867 of a microlens of the imaging pixel 874 is offset in a second direction that is opposite the first direction. Pixel1 and Pixel2 of off-axis imaging pixel 874 may be considered subpixels of off-axis imaging pixel 874.

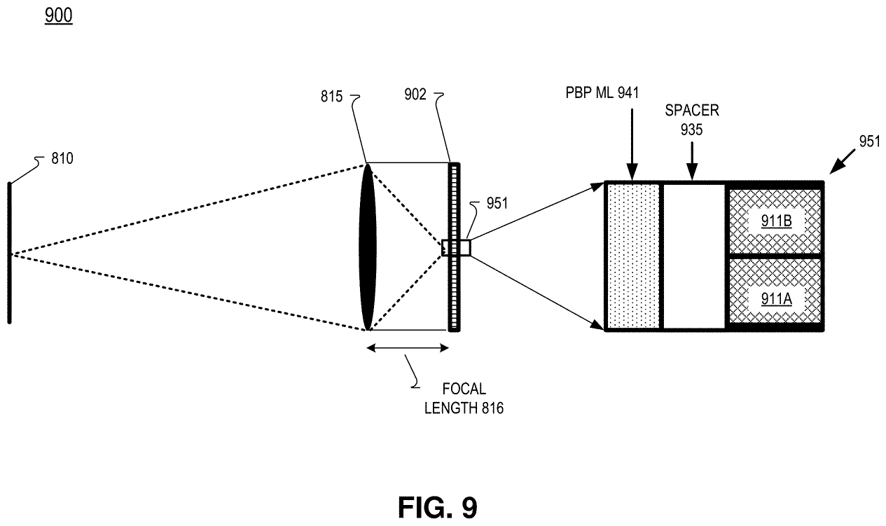

FIG. 9 illustrates an imaging system 900 that utilizes a patterned PBP lens 941 to function as a microlens and to direct LHC polarized light and RHC polarized light to different subpixels, in accordance with aspects of the disclosure. Imaging system 900 includes an object 810, a focusing element 815 having a focal length 816, and an image pixel array 902. Focusing element 815 focuses image light scattered/reflected from object 810 to image pixel array 902. Image pixel array 902 includes a plurality of image pixels such as image pixel 951. Image pixel 951 includes a first subpixel 911A and a second subpixel 911B. A spacer 935 may be disposed between PBP lens 941 first subpixel 911A and a second subpixel 911B.

First subpixel 911A is configured to receive RHC polarized light and second subpixel 911B is configured to receive LHC polarized light. PBP lens 941 may be configured to focus image light to subpixels 911A and 911B while also being configured with the functionality of LC-PBP 230 of FIGS. 2A and 2B to direct the RHC light to subpixel 911A while directing the LHC light to subpixel 911B. Hence, an additional refractive microlens layer may not be needed in system 900. Although not particularly illustrated, a patterned PBP lens 941 may be disposed over image pixel array 902 where the patterned PBP lens 941 has various regions that are disposed over each image pixel with a one-to-one correspondence.

Embodiments of the invention may include or be implemented in conjunction with an artificial reality system. Artificial reality is a form of reality that has been adjusted in some manner before presentation to a user, which may include, e.g., a virtual reality (VR), an augmented reality (AR), a mixed reality (MR), a hybrid reality, or some combination and/or derivatives thereof. Artificial reality content may include completely generated content or generated content combined with captured (e.g., real-world) content. The artificial reality content may include video, audio, haptic feedback, or some combination thereof, and any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to, e.g., create content in an artificial reality and/or are otherwise used in (e.g., perform activities in) an artificial reality. The artificial reality system that provides the artificial reality content may be implemented on various platforms, including a head-mounted display (HMD) connected to a host computer system, a standalone HMD, a mobile device or computing system, or any other hardware platform capable of providing artificial reality content to one or more viewers.

The term “processing logic” (e.g. processing logic 712) in this disclosure may include one or more processors, microprocessors, multi-core processors, Application-specific integrated circuits (ASIC), and/or Field Programmable Gate Arrays (FPGAs) to execute operations disclosed herein. In some embodiments, memories (not illustrated) are integrated into the processing logic to store instructions to execute operations and/or store data. Processing logic may also include analog or digital circuitry to perform the operations in accordance with embodiments of the disclosure.

A “memory” or “memories” described in this disclosure may include one or more volatile or non-volatile memory architectures. The “memory” or “memories” may be removable and non-removable media implemented in any method or technology for storage of information such as computer-readable instructions, data structures, program modules, or other data. Example memory technologies may include RAM, ROM, EEPROM, flash memory, CD-ROM, digital versatile disks (DVD), high-definition multimedia/data storage disks, or other optical storage, magnetic cassettes, magnetic tape, magnetic disk storage or other magnetic storage devices, or any other non-transmission medium that can be used to store information for access by a computing device.

Networks may include any network or network system such as, but not limited to, the following: a peer-to-peer network; a Local Area Network (LAN); a Wide Area Network (WAN); a public network, such as the Internet; a private network; a cellular network; a wireless network; a wired network; a wireless and wired combination network; and a satellite network.

Communication channels may include or be routed through one or more wired or wireless communication utilizing IEEE 802.11 protocols, BlueTooth, SPI (Serial Peripheral Interface), FC (Inter-Integrated Circuit), USB (Universal Serial Port), CAN (Controller Area Network), cellular data protocols (e.g. 3G, 4G, LTE, 5G), optical communication networks, Internet Service Providers (ISPs), a peer-to-peer network, a Local Area Network (LAN), a Wide Area Network (WAN), a public network (e.g. “the Internet”), a private network, a satellite network, or otherwise.

A computing device may include a desktop computer, a laptop computer, a tablet, a phablet, a smartphone, a feature phone, a server computer, or otherwise. A server computer may be located remotely in a data center or be stored locally.

The processes explained above are described in terms of computer software and hardware. The techniques described may constitute machine-executable instructions embodied within a tangible or non-transitory machine (e.g., computer) readable storage medium, that when executed by a machine will cause the machine to perform the operations described. Additionally, the processes may be embodied within hardware, such as an application specific integrated circuit (“ASIC”) or otherwise.

A tangible non-transitory machine-readable storage medium includes any mechanism that provides (i.e., stores) information in a form accessible by a machine (e.g., a computer, network device, personal digital assistant, manufacturing tool, any device with a set of one or more processors, etc.). For example, a machine-readable storage medium includes recordable/non-recordable media (e.g., read only memory (ROM), random access memory (RAM), magnetic disk storage media, optical storage media, flash memory devices, etc.).

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

What is claimed is:

1. An image sensor comprising:
a first subpixel configured to sense a vertically polarized portion of imaging light;
a second subpixel configured to sense a 45 degree polarized portion of the imaging light;
a third subpixel configured to sense a horizontally polarized portion of the imaging light;
a fourth subpixel configured to sense a 135 degree polarized portion of the imaging light; and
a patterned liquid crystal polarizer (LCP) layer having: (1) a vertical polarizing region disposed over the first subpixel; (2) a 45 degree polarizing region disposed over the second subpixel; (3) a horizontal polarizing region disposed over the third subpixel; and (4) a 135 degree polarizing region disposed over the fourth subpixel.

2. The image sensor of claim 1, wherein the patterned LCP layer is contiguous across the first subpixel, the second subpixel, the third subpixel, and the fourth subpixel.

3. The image sensor of claim 1 further comprising:
a fifth subpixel configured to sense a right hand circularly polarized (RHCP) portion of the imaging light; and
a sixth subpixel configured to sense a left hand circularly polarized (LHCP) portion of the imaging light.

4. The image sensor of claim 3, wherein the fifth subpixel includes a right-hand circular polarizer region having a quarter-waveplate (QWP) and a horizontal polarizer, and wherein the sixth subpixel includes a left-hand circular polarizer region including a quarter-waveplate (QWP) and a vertical polarizer.

5. The image sensor of claim 4, wherein the patterned LCP layer includes the horizontal polarizer and the vertical polarizer.

6. The image sensor of claim 3 further comprising: a liquid crystal Pancharatnam-Berry Phase (LC-PBP) lens disposed over the fifth subpixel and the sixth subpixel, wherein the LC-PBP lens is configured to direct the RHCP portion of the imaging light to the fifth subpixel and configured to direct the LHCP portion of the imaging light to the sixth subpixel.

7. The image sensor of claim 3 further comprising:
processing logic configured to receive;
a first signal from the first subpixel;
a second signal from the second subpixel;
a third signal from the third subpixel;
a fourth signal from the fourth subpixel;
a fifth signal from the fifth subpixel; and
a sixth signal from the sixth subpixel, wherein the processing logic is configured to generate a full-Stokes image in response to the first signal, the second signal, the third signal, the fourth signal, the fifth signal, and the sixth signal.

8. The image sensor of claim 3 further comprising:
a first microlens configured to focus the imaging light to the first subpixel, the second subpixel, the third subpixel, and the fourth subpixel; and
a second microlens configured to focus the imaging light to the fifth subpixel and the sixth subpixel.

9. The image sensor of claim 1, wherein the patterned LCP layer includes twisted liquid crystals and untwisted liquid crystals.

10. The image sensor of claim 1, wherein the patterned LCP layer includes photoaligned absorbing materials dimensioned at less than 10 microns.

11. The image sensor of claim 1 further comprising:
processing logic configured to receive;
a first signal from the first subpixel;
a second signal from the second subpixel;
a third signal from the third subpixel; and
a fourth signal from the fourth subpixel, wherein the processing logic is configured to generate a partial-Stokes image in response to the first signal, the second signal, the third signal, and the fourth signal.

12. A polarization-difference image sensor comprising:
imaging pixels having a first subpixel and a second subpixel, wherein the first subpixel is configured to sense a right hand circularly polarized (RHCP) portion of imaging light, and wherein the second subpixel is configured to sense a left hand circularly polarized (LHCP) portion of the imaging light; and
a liquid crystal Pancharatnam-Berry Phase (LC-PBP) lens layer disposed over the imaging pixels, wherein the LC-PBH lens layer is configured to:
direct the RHCP portion of the imaging light to the first subpixels of the imaging pixels; and
direct the LHCP portion of the imaging light to the second subpixels of the imaging pixels.

13. The polarization-difference image sensor of claim 12, wherein the imaging pixels include:
an on-axis pixel; and
an off-axis pixel disposed closer to an outside boundary of the polarization-difference image sensor than the on-axis pixel, wherein the first subpixel and the second subpixel of the off-axis pixel has a larger semiconductor substrate size than the first subpixel and the second subpixel of the on-axis pixel.

14. The polarization-difference image sensor of claim 12, wherein the imaging pixels include:
an on-axis pixel; and
an off-axis pixel disposed closer to an outside boundary of the polarization-difference image sensor than the on-axis pixel, wherein a dividing line between the first subpixel and the second subpixel is offset from the LC-PBP in a first direction, and wherein an optical axis of a microlens of the imaging pixel is offset in a second direction that is opposite the first direction.

15. The polarization-difference image sensor of claim 12, wherein the imaging pixels include a third subpixel and a fourth subpixel configured to sense an intensity of the imaging light, the third subpixel disposed adjacent to the first subpixel and the second subpixel and the fourth subpixel disposed adjacent to the first subpixel and the second subpixel.

16. The polarization-difference image sensor of claim 12, wherein the imaging pixels include a third subpixel and a fourth subpixel configured to sense an infrared intensity of the imaging light.

17. A polarization-difference image sensor comprising:
imaging pixels having a first subpixel and a second subpixel, wherein the first subpixel is configured to sense a first linear polarization orientation portion of imaging light, and wherein the second subpixel is configured to sense a second linear polarization orientation portion of the imaging light, wherein the first linear polarization orientation is orthogonal to the second linear polarization orientation; and
a patterned liquid crystal polarizer (LCP) layer having;
first polarizing regions disposed over the first subpixels and configured to pass the first linear polarization orientation to the first subpixels of the imaging pixels; and
second polarizing regions disposed over the second subpixels and configured to pass the second linear polarization orientation to the second subpixels of the imaging pixels.

18. The polarization-difference image sensor of claim 17, wherein the first linear polarization orientation is horizontal and the second linear polarization orientation is vertical.

19. The polarization-difference image sensor of claim 17 further comprising:
processing logic configured to, for each of the imaging pixels, to subtract a first signal received from the first subpixel from a second signal received from the second subpixel.

20. The polarization-difference image sensor of claim 17, wherein the imaging pixels include a third subpixel and a fourth subpixel, the third subpixel disposed adjacent to the first subpixel and the second subpixel and the fourth subpixel disposed adjacent to the first subpixel and the second subpixel.
